(19) United States
(12) Patent Application Publication
(10) Pub. No.: US 2005/0239268 A1
(43) Pub. Date: Oct. 27, 2005

(54) Integrated circuit with removable scribe street trim and test pads

(75) Inventors: Rex W. Pirkle, Denison, TX (US); Sean M. Malolepszy, Sherman, TX (US); Eric M. Bernard, Sherman, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/829,827

(22) Filed: Apr. 22, 2004

(51) Int. Cl. H01L 21/301

(52) U.S. Cl. 438/460

(57) ABSTRACT

A method comprises forming a pad in a scribe street adjacent to an integrated circuit (“IC”), electrically connecting the pad to the IC, and sawing the scribe street. A wafer is also disclosed as comprising an IC, a scribe street and a pad formed in the scribe street.

### BACKGROUND

Various integrated circuit (“IC”) manufacturing processes may introduce minor structural errors into the circuit. Such errors may comprise, for example, resistances in various parts of the IC that are different than the resistances specified by a designer. A “trim circuit” is a type of circuit that may be used to correct for such errors. In general, a trim circuit is able to adjust various sections of the IC and generally comprises trim pads onto which adjustment signals may be delivered. The adjustment signals electrically manipulate the trim circuit to correct for the errors. Even though the trim pads are used only during manufacturing and prior to packaging of the IC, the trim pads remain on the die, thereby wasting valuable space on the die.

### BRIEF SUMMARY

The problems noted above are solved at least in part by a method for reducing chip size by relocating trim pads. One exemplary embodiment may comprise forming a pad in a scribe street adjacent to an integrated circuit (“IC”), electrically connecting the pad to the IC, and sawing the scribe street. In other embodiments, a wafer comprises an IC, a scribe street adjacent to the IC, and a pad formed in the scribe street. The pad is electrically connected to the IC.

### BRIEF DESCRIPTION OF THE DRAWINGS

For a detailed description of exemplary embodiments of the invention, reference will now be made to the accompanying drawings in which:

FIG. 1 illustrates a portion of a wafer in accordance with a preferred embodiment of the invention and containing trim circuits formed in the “streets” surrounding an IC;

FIG. 2a illustrates the layout of a conventional IC;

FIG. 2b illustrates a layout of an IC in accordance with preferred embodiments of the invention;

FIG. 3 illustrates an alternative embodiment of a wafer containing trim circuits; and

FIG. 4 illustrates a flow diagram in accordance with a preferred embodiment of the invention.

### NOTATION AND NOMENCLATURE

Certain terms are used throughout the following description and claims to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” Also, the term “couple” or “couples” is intended to mean either an indirect or direct electrical connection. Thus, if a first device couples to a second device, that connection may be through a direct electrical connection, or through an indirect electrical connection by way of other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Various IC layout embodiments are described herein that result in a more efficient use of die surface area. Also described are techniques for enhancing multiprobe testing performance and process monitor capability by using scribe street test pads.

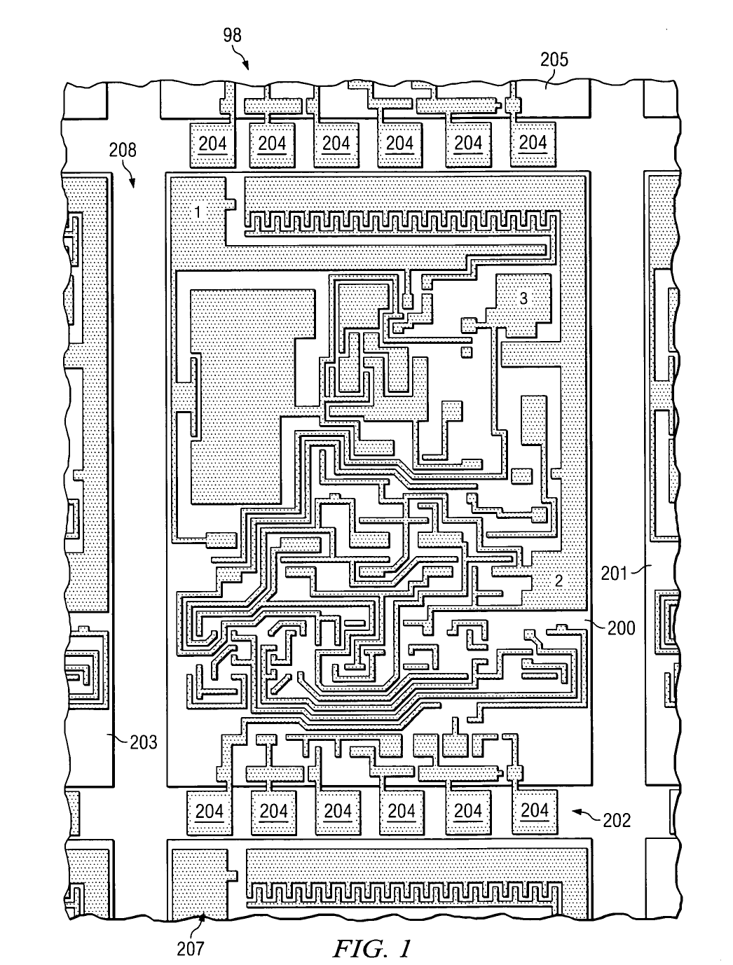

FIG. 1 illustrates a portion of a wafer 98. The portion shown includes an IC 200 and portions of adjacent ICs 201, 203, 205, and 207. “Scribe streets” delineate the boundaries between ICs. For example, scribe street 208 separates IC 200 from IC 203 and scribe street 202 separates IC 200 from IC 207. The various ICs 200, 201, 203, 205, and 207 can be separated from the wafer by a sawing operation in which a saw cuts along the scribe streets, thereby separating the various ICs into individual chips. The wafer 98 of FIG. 1 comprises one or more trim pads 204. In accordance with the preferred embodiment, the trim pads 204 are placed in the scribe streets instead of on the IC 200. In the example of FIG. 1, trim pads 204 are located in scribe street 202. After the trim pads are used to adjust the IC 200, the IC 200 is separated from the wafer by cutting along the scribe streets, including scribe street 202. Cutting scribe street 202 may involve cutting through trim pads 204, wherein at least a portion of the trim pads 204 may be removed. Cutting trim pads 204 is acceptable because the trim pads 204 will already have been used for their intended purpose by the time the sawing operation occurs. Moreover, forming the trim pads 204 in the scribe streets means that the trim pads do not occupy space, or at least occupy less space, on the IC 200 than would otherwise be the case.

During conventional wafer saw operation, it is undesirable to have metal in the scribe street. Metal in the scribe street tends to clog saw blades and requires slower cutting rates in production. In at least some embodiments, because the trim pads 204 may clog the saw blades, the trim pads 204 may be etched away to clear the scribe street 202 after their use and prior to the saw operation. Such an embodiment may comprise applying an etch-resist over the IC 200 so that only the scribe streets 202, 208 and the trim pads 204 are exposed. Then, at least a portion of the trim pad(s) 204 may be etched away, and subsequently the etch-resist may be removed from the IC 200.

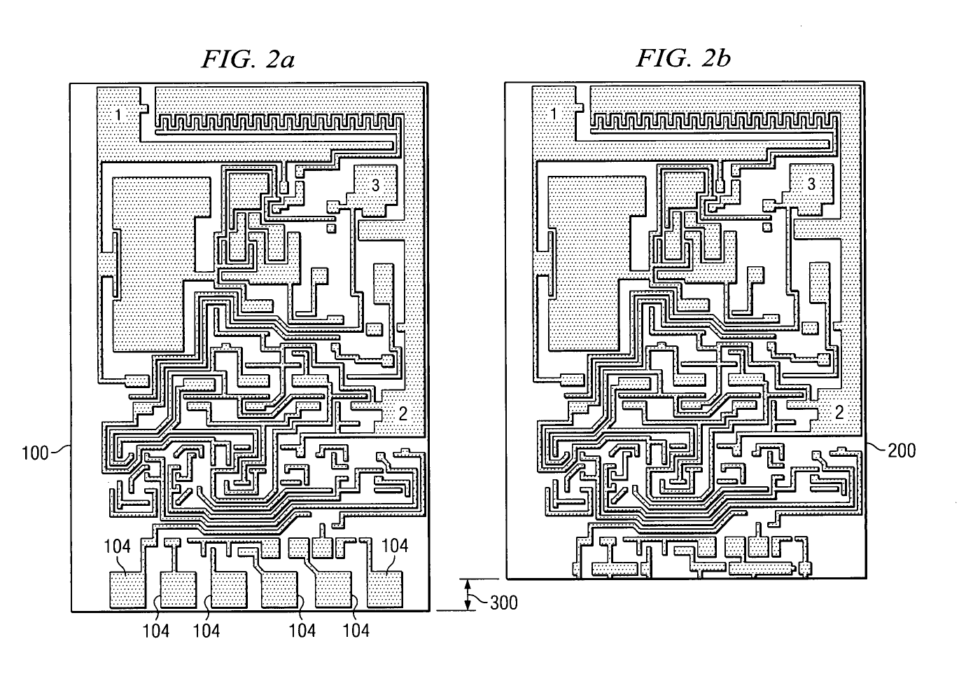

FIG. 2a illustrates a conventional IC layout 100 after a saw operation. In FIG. 2a, trim pads 104 are located on the IC 100 and thus remain on the IC 100 after the saw operation. Conversely, FIG. 2b shows IC 200 without the trim pads 204, which were removed during the saw operation as explained above. Because conventional chip 100 still comprises the trim pads 104 and the preferred IC 200 does not comprise the trim pads 204, the IC 200 achieves a reduction in size (designated by reference numeral 300) relative to the IC 100 that is approximately the width of a trim pad 104 or a trim pad 204. The reduction in size 300 enables designers to house the IC 200 in a smaller package and also reduces manufacturing costs.

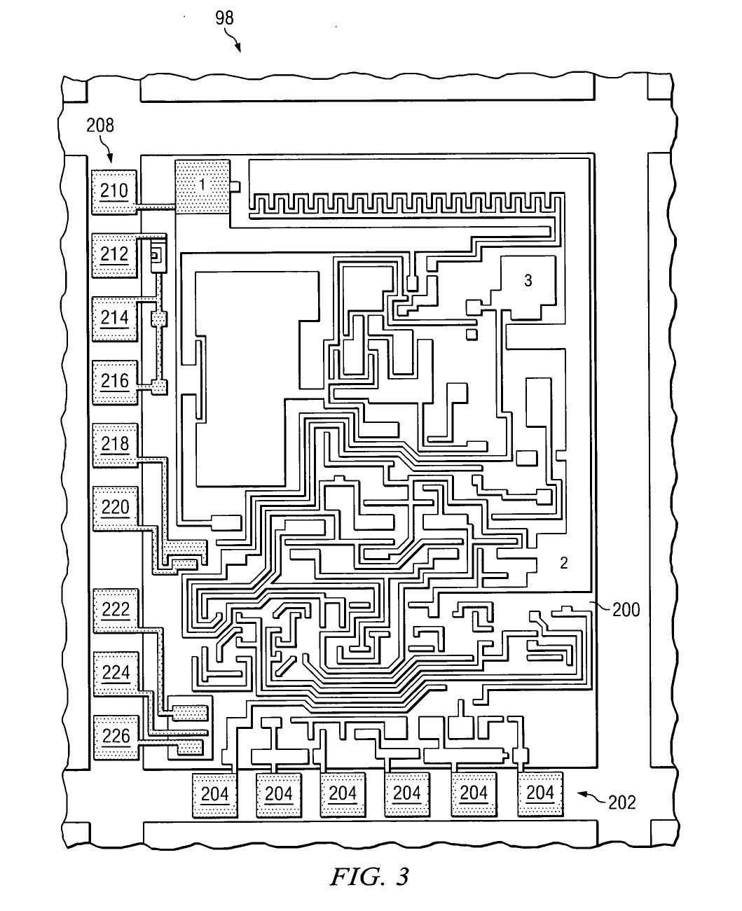

Applications of the above technique are not limited to trim circuits. In at least some embodiments, placing test pads in a scribe street may enable a designer to add to a layout test geometries and/or process monitor structures that would otherwise occupy a certain amount of space on a chip. Such a technique may be used to enhance process control, expand capability to monitor various circuit components, and/or improve testing capability during a multiprobe testing session. One such embodiment is illustrated in the embodiment of FIG. 3. FIG. 3 shows a wafer 98 comprising a bond pad 209 within IC 200, a scribe street 202 comprising one or more trim pads 204, and a scribe street 208 comprising one or more test pads 210-226. As shown, test pad 210 is electrically connected to the bond pad 209. The bond pad 209 may be used as a “Kelvin” termination point, thus improving measurement accuracy during a multiprobe testing session. More specifically, because conventional test methods may employ a measurement probe needle to be directly connected to the bond pad 209, a Kelvin termination point is present at the probe needle shoulder. Because the Kelvin termination point is at the probe needle shoulder, resistance introduced by the interface between the bond pad 209 and the probe tip results in substantial voltage measurement error under high current conditions. Instead, forming a test pad 210 in the scribe street 208 and electrically connecting the test pad 210 to the bond pad 209 (as shown in FIG. 3) results in a Kelvin termination point at the probe tip when the probe tip is touched to the bond pad 209. A low current sense path is provided by test pad 210, thus desirably reducing voltage measurement error. Because the test pad 210 may be useful only during a multiprobe testing session, the test pad 210 may be removed during a saw operation as described above.

Linear device test specifications may require various components not already on the IC 200 (e.g., capacitors, diodes, resistors, transistors, inductors) in parametric testing. Such components may be attached to the IC 200 and interfaced to multiprobe testing equipment using the test pads 212-226. For example, the pad pairs 212 and 214, 214 and 216, 218 and 220 may be electrically connected to a diode, resistor, and capacitor, respectively. Further, pads 222-226 may be connected to a transistor such as an NPN transistor. In general, any electrical component may be coupled to the IC 200 for purposes of process monitoring during a multiprobe testing session or experimental measurement session.

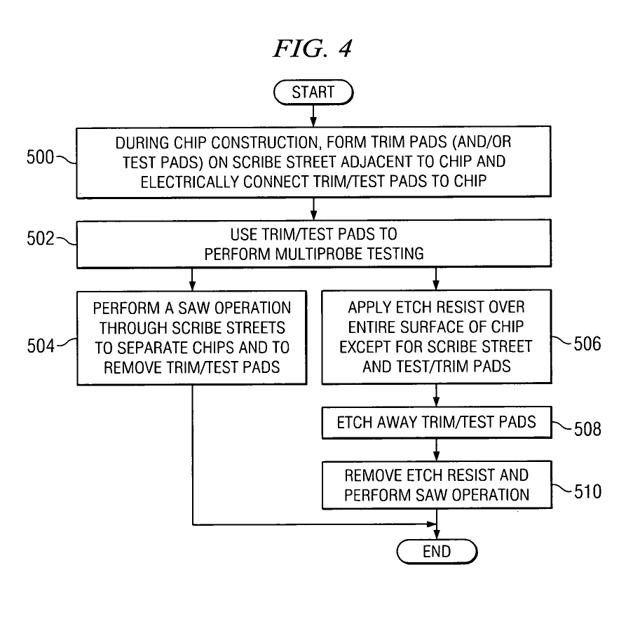

FIG. 4 illustrates a process by which any of the exemplary embodiments shown in FIGS. 1-3 may be implemented. The process may begin with forming trim pads and/or test pads on a scribe street adjacent to an IC and electrically connecting the trim pads/test pads to the IC during chip construction (block 500). The trim pads/test pads subsequently may be used as desired during a multiprobe testing session (block 502). In some embodiments, the trim pads/test pads may be removed by performing a saw operation through the scribe streets (block 504). In other embodiments, the trim pads/test pads may be removed by first applying an etch resist over some or all areas of the chip except for the scribe streets and the trim pads/test pads (block 506). The trim pads/test pads then may be etched away using any appropriate technique (block 508). Finally, the trim pads/test pads may be removed by removing the etch resist and performing a saw operation (block 510).

The above discussion is meant to be illustrative of the principles and various embodiments of the present invention. Numerous variations and modifications will become apparent to those skilled in the art once the above disclosure is fully appreciated. For example, the techniques described above may apply to diode trim circuits, fuse trim circuits, non-trim circuits and/or any appropriate circuit. The techniques also may be used to provide probe access to device nodes on the chip that would otherwise be unmeasurable. It is intended that the following claims be interpreted to embrace all such variations and modifications.

1. A method, comprising:
forming a pad in a scribe street adjacent to an integrated circuit (“IC”);
electrically connecting the pad to the IC; and
sawing the scribe street.

2. The method of claim 1, wherein forming the pad comprises forming a trim pad used to adjust the IC.

3. The method of claim 1, wherein forming the pad comprises forming a test pad used to test the IC.

4. The method of claim 1, wherein sawing the scribe street comprises removing at least a portion of the pad.

5. The method of claim 1, further comprising removing the pad by:
applying an etch resist to at least some areas of the IC except for the pad and the scribe street containing the pad; and
etching away the pad.

6. The method of claim 1, wherein electrically connecting the pad to the IC comprises electrically connecting the pad to at least one component selected from the group consisting of resistors, transistors, capacitors, inductors, and diodes.

7. The method of claim 1, wherein electrically connecting the pad to the IC comprises electrically connecting the pad to a bond pad formed on the IC.

8. The method of claim 1, wherein forming the pad comprises forming a pad in a scribe street adjacent to an IC that comprises a trim circuit.

9. The method of claim 1, further comprising forming a plurality of pads in a scribe street adjacent to an IC that comprises a trim circuit.

10. A wafer, comprising:
an IC;
a scribe street adjacent to said IC; and
a pad formed in the scribe street, said pad electrically connected to the IC.

11. The wafer of claim 10, wherein the pad comprises a trim pad used to adjust the IC.

12. The wafer of claim 10, wherein the pad comprises a test pad used to test the IC.

13. The wafer of claim 10, wherein at least a portion of said pad is removed using a saw operation.

14. The wafer of claim 10, wherein the pad is coupled to at least one component selected from the group consisting of diodes, transistors, inductors, resistors, and capacitors.

15. The wafer of claim 10, wherein the pad is electrically connected to a bond pad of the IC.

16. The wafer of claim 10, wherein the IC comprises a trim circuit.

17. The wafer of claim 10, wherein the scribe street contains a plurality of pads.
